(19) United States
(12) Patent Application Publication
(10) Pub. No.: US 2026/0123113 A1
(43) Pub. Date: Apr. 30, 2026

(54) LIGHT-EMITTING STRUCTURE, METHOD FOR MANUFACTURING LIGHT-EMITTING STRUCTURE, AND DISPLAY DEVICE

(71) Applicant: HKC CORPORATION LIMITED, Shenzhen (CN)

(72) Inventors: Ranlong WANG, Shenzhen (CN); Yang PU, Shenzhen (CN); Haijiang YUAN, Shenzhen (CN)

(21) Appl. No.: 19/328,583

(22) Filed: Sep. 15, 2025

(30) Foreign Application Priority Data
Oct. 24, 2024 (CN) 202411490277.7

(51) Int. Cl. H10H 20/841; H10H 29/01; H10H 29/24

(52) U.S. Cl. CPC H10H 20/841; H10H 29/034; H10H 29/24

(57) ABSTRACT

A light-emitting structure includes a substrate and a plurality of light-emitting units arranged in an array and spaced apart on the substrate. In the light-emitting unit, the second-type doped layer and the first-type doped layer are in contact with opposite sides of the light-emitting layer. The surface of the second-type doped layer facing away from the substrate is flush with the surface of the first-type doped layer facing away from the substrate. The first-type electrode is in contact with the surface of the first-type doped layer facing away from the substrate, and the second-type electrode is in contact with the surface of the second-type doped layer facing away from the substrate. The surface of the first-type electrode facing away from the substrate is flush with the surface of the second-type electrode facing away from the substrate.

### CROSS-REFERENCE TO RELATED APPLICATIONS

The present application claims priority to Chinese Patent Application No. 202411490277.7, filed on Oct. 24, 2024, the entire disclosure of which is hereby incorporated herein by reference.

### TECHNICAL FIELD

The present application relates to the technical field of display, and particularly to a light-emitting structure, a method for manufacturing the light-emitting structure, and a display device.

### BACKGROUND

Micro Light-Emitting Diode (Micro LED) shows its prowess in some display products due to its advantages such as high color saturation, high resolution, and high brightness, especially in high pixel-per-inch (PPI) products like Augmented Reality (AR)/Virtual Reality (VR).

As shown in FIG. 1, currently, micro LEDs mainly have three structures: front-mounted, flip-chip, and vertical. Since the surface of the first-type electrode close to the first-type doped layer and the surface of the second-type electrode close to the second-type doped layer in the micro LED are not on the same horizontal plane, it is difficult to ensure that the surface of the first-type electrode away from the first-type doped layer is flush with the surface of the second-type electrode away from the second-type doped layer during manufacturing, thereby increasing the difficulty of bonding the micro LED to the driving substrate.

### SUMMARY

There are provided a light-emitting structure, a method for manufacturing the light-emitting structure, and a display device according to embodiments of the present application. The technical solution is as below.

According to a first aspect of embodiments of the present application, there is provided a light-emitting structure, which includes:
a substrate;
a plurality of light-emitting units provided in an array and at intervals on the substrate;
where the light-emitting unit includes a light-emitting layer, a first-type doped layer, a second-type doped layer, a first-type electrode and a second-type electrode;
in the light-emitting unit: the second-type doped layer and the first-type doped layer are in contact with opposite sides of the light-emitting layer, a surface of the second-type doped layer away from the substrate is flush with a surface of the first-type doped layer away from the substrate;
the first-type electrode is in contact with the surface of the first-type doped layer away from the substrate, and the second-type electrode is in contact with the surface of the second-type doped layer away from the substrate; and
the surface of the first-type electrode away from the substrate is flush with the surface of the second-type electrode away from the substrate.

According to a second aspect of embodiments of the present application, there is provided a method for manufacturing a light-emitting structure, which includes:
providing a substrate;
forming a plurality of light-emitting layers provided in an array and at intervals on the substrate;
respectively providing a first-type doped layer and a second-type doped layer on opposite sides of each light-emitting layer, so that both the second-type doped layer and the first-type doped layer are in contact with the opposite sides of the light-emitting layer, and a surface of the second-type doped layer away from the substrate is flush with a surface of the first-type doped layer away from the substrate;
forming a first-type electrode on a side of each first-type doped layer away from the substrate, and forming a second-type electrode on a side of each second-type doped layer away from the substrate, to form a plurality of light-emitting units provided in an array and at intervals on the substrate;
where the first-type electrode is in contact with the surface of the first-type doped layer away from the substrate, the second-type electrode is in contact with the surface of the second-type doped layer away from the substrate, and the surface of the first-type electrode away from the substrate is flush with a surface of a corresponding second-type electrode away from the substrate.

According to a third aspect of embodiments of the present application, there is provided a display device, which includes a main board and any one of the light-emitting structure as mentioned above, the main board is electrically connected to each light-emitting unit in the light-emitting structure.

Other features and advantages of the present application will become apparent through the following detailed description, or be partially acquired through the practice of the present application.

It should be understood that the above general description and the following detailed description are merely exemplary and explanatory, and cannot limit the present application.

### BRIEF DESCRIPTION OF THE DRAWINGS

The accompanying drawings here are incorporated into the specification and constitute a part of this specification, showing the embodiments that conform to the present application, and are used together with the specification to explain the principles of the present application. Obviously, the accompanying drawings in the following description are only some embodiments of the present application. For those skilled in the art, other accompanying drawings can be obtained based on these accompanying drawings without creative efforts.

FIG. 1 is a schematic structural view of three types of micro LEDs in the related art.

FIG. 2 is a schematic cross-sectional structural view of a light-emitting structure in an embodiment of the present application.

FIG. 3 is a schematic structural view of a light-emitting side of the light-emitting layer in an embodiment of the present application.

FIG. 4 is another schematic cross-sectional structural view of a light-emitting structure in an embodiment of the present application.

FIG. 5 is a schematic flowchart of a method for manufacturing the light-emitting structure in an embodiment of the present application.

FIG. 6 is a schematic cross-sectional structural view of successively forming a buffer layer, a light-emitting material and a protective material on the substrate in an embodiment of the present application.

FIG. 7 is a schematic cross-sectional structural view of forming a light-emitting layer and a protective layer after patterning in an embodiment of the present application.

FIG. 8 is a schematic flowchart of forming a first-type doped layer in an embodiment of the present application.

FIG. 9 is a schematic flowchart of forming a second-type doped layer in an embodiment of the present application.

FIG. 10 is a schematic cross-sectional structural view of forming a reflective layer in an embodiment of the present application.

FIG. 11 is a schematic flowchart of transferring the light-emitting units to the driving substrate after the light-emitting structure is formed in an embodiment of the present application.

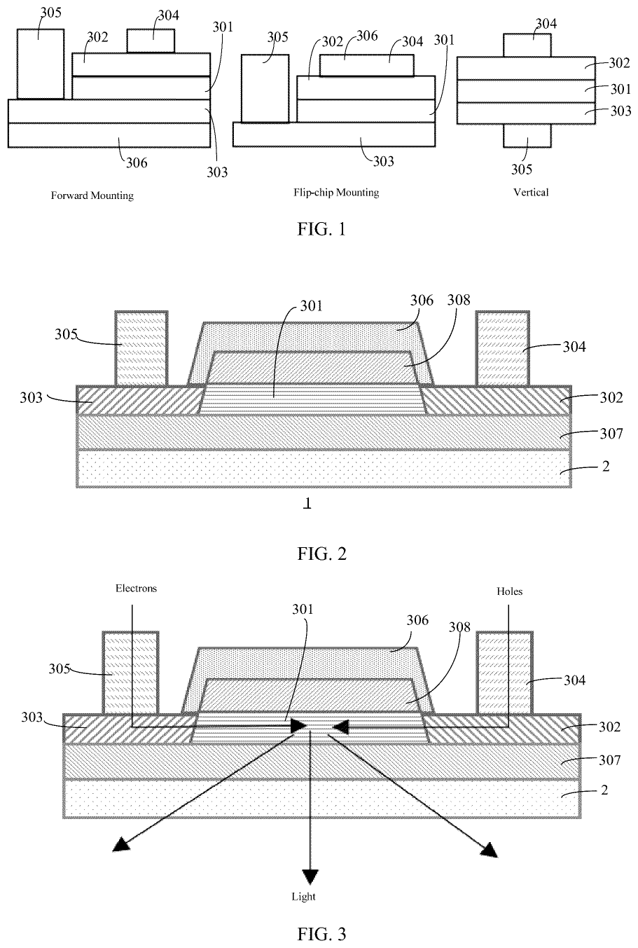

### DETAILED DESCRIPTION OF THE EMBODIMENTS

Now, the example embodiments will be described more comprehensively with reference to the accompanying drawings. However, the example embodiments can be implemented in various forms and should not be construed as being limited to the examples set forth herein. Instead, these embodiments are provided so that the present application will be more comprehensive and complete, and the concept of the example embodiments will be fully conveyed to those skilled in the art.

Moreover, the described features, structures, or characteristics can be combined in any suitable manner in one or more embodiments. In the following description, many specific details are provided to give a full understanding of the embodiments of the present application. However, those skilled in the art will realize that the technical solutions of the present application can be practiced without one or more of the specific details, or other methods, components, devices, steps, etc. can be adopted. In other cases, well-known methods, devices, implementations, or operations are not shown or described in detail to avoid obscuring various aspects of the present application.

Hereinafter, the present application will be further described in detail with reference to the accompanying drawings and specific embodiments. It should be noted here that the technical features involved in the various embodiments of the present application described below can be combined with each other as long as they do not conflict with each other. The embodiments described below with reference to the accompanying drawings are exemplary and are intended to explain the present application, and should not be construed as a limitation to the present application.

In the embodiments of the present application, the light-emitting unit 3 may also include both a protective layer 308 and a reflective layer 306. At this time, the protective layer 308 covers the outer surface of the light-emitting layer 301, and the protective layer 308 can be in direct contact with the outer surface of the light-emitting layer 301 to protect the integrity and light-emitting performance of the light-emitting layer 301. The reflective layer 306 can cover the surface of the protective layer 308 away from the light-emitting layer 301 and the peripheral side surface of the protective layer 308. Thus, the light emitted to the non-light-emitting side of the light-emitting layer 301 can be reflected to the light-emitting side of the light-emitting layer 301 through the reflective layer 306, so as to improve the light-emitting rate and enhance the light-emitting brightness of the light-emitting structure 1.

As shown in FIG. 2, the present application provides a light-emitting structure 1, which includes a substrate 2 and a plurality of light-emitting units 3. The plurality of light-emitting units 3 are provided in an array and at intervals on the substrate 2.

The light-emitting unit 3 includes a light-emitting layer 301, a first-type doped layer 302, a second-type doped layer 303, a first-type electrode 304, and a second-type electrode 305.

The light-emitting layers 301 in each light-emitting unit 3 are provided in an array and at intervals on the substrate 2, and each second-type doped layer 303 and each first-type doped layer 302 are also provided at intervals.

In each light-emitting unit 3, the first-type doped layer 302 and the second-type doped layer 303 are in contact with the opposite sides of the light-emitting layer 301.

Specifically, in the embodiments of the present application, the second-type doped layer 303 and the first-type doped layer 302 are respectively located on the opposite sides of the light-emitting layer 301 and are respectively in contact with part of the peripheral side surfaces on the opposite sides of the light-emitting layer 301, and the surface of the second-type doped layer 303 away from the substrate 2 is flush with the surface of the first-type doped layer 302 away from the substrate 2.

The first-type electrode 304 is located on the side of the first-type doped layer 302 away from the substrate 2, and the first-type electrode 304 is in contact with the surface of the first-type doped layer 302 away from the substrate. The second-type electrode 305 is located on the side of the second-type doped layer 303 away from the substrate 2, and the second-type electrode 305 is in contact with the surface of the second-type doped layer 303 away from the substrate. The surface of the first-type electrode 304 away from the substrate 2 is flush with the surface of the second-type electrode 305 away from the substrate 2.

In the present application, the first-type doped layer 302 and the second-type doped layer 303 are formed on the opposite sides of the light-emitting layer 301 respectively and the surface of the first-type doped layer 302 away from the substrate 2 is made to be flush with the surface of the second-type doped layer 303 away from the substrate 2, the first-type electrode 304 and the second-type electrode 305 can be fabricated on the same horizontal plane, to reduce or avoid the height difference between the surface of the first-type electrode 304 away from the substrate 2 and the surface of the second-type electrode 305 away from the substrate 2, thereby reducing the difficulty of bonding each light-emitting unit 3 to the driving substrate 4, to ensure the normal light emission of each light-emitting unit 3 in the light-emitting structure 1.

Meanwhile, since the first-type electrode 304 and the second-type electrode 305 can be fabricated on the same horizontal plane, when manufacturing the first-type electrode 304 and the second-type electrode 305 with the same height, the process difficulty can be greatly reduced, and thus the production efficiency of the light-emitting structure 1 can be improved. In some embodiments of the present application, in the direction away from the substrate 2, the outer peripheral side of the light-emitting layer 301 inclines towards the center of the light-emitting layer 301.

For example, the included angle θ between the outer peripheral side of the light-emitting layer 301 and the substrate 2 in the present application can be greater than or equal to 45° and less than 90°. For instance, the value of the included angle θ can be 45°, 50°, 55°, 60°, 65°, 70°, 75°, 80°, 85°, etc., but it is not limited thereto. The value of the included angle θ can be adjusted according to the actual situation of each light-emitting unit 3.

It should be noted that when the included angle θ between the outer peripheral side of the light-emitting layer 301 and the substrate 2 is 90°, it is very easy to cause poor contact of the light-emitting layer 301 with the first-type doped layer 302 and the second-type doped layer 303, which may affect the injection of electrons and holes into the light-emitting layer 301 and the light-emitting effect of the light-emitting layer 301. When θ is less than 45°, the surface of the light-emitting layer 301 away from the substrate 2 is too small, which will lead to a relatively small overall volume of the light-emitting layer 301 and thus reduce the overall light-emitting brightness of the light-emitting layer 301.

In addition, the first-type doped layer 302 and the second-type doped layer 303 in the present application can be formed by means of deposition. When θ is greater than 90°, the overall shape of the light-emitting layer 301 is an inverted trapezoid. When the light-emitting layer 301 is formed and the first-type doped layer 302 and the second-type doped layer 303 are deposited on the opposite sides of the light-emitting layer 301, it is difficult for the first-type doped layer 302 and the second-type doped layer 303 to contact the outer peripheral side of the light-emitting layer 301, which will affect the light-emitting effect of the light-emitting structure 1.

In the present application, since the included angle θ between the outer peripheral side of the light-emitting layer 301 and the substrate 2 is less than 90°, a good contact of the light-emitting layer 301 with the first-type doped layer 302 and the second-type doped layer 303 is ensured. Meanwhile, since θ is greater than or equal to 45°, the situation where the surface of the light-emitting layer 301 away from the substrate 2 is too small is avoided, thereby ensuring that the light-emitting layer 301 has enough space for the recombination of electrons and holes, and thus ensuring the good light-emitting effect of the light-emitting layer 301.

In addition, when the height of the light-emitting layer 301 is the same, compared with the scheme where θ is equal to 90°, since θ is greater than or equal to 45° and less than 90°, the contact surface of the first-type doped layer 302 with the second-type doped layer 303 and the light-emitting layer 301 is increased, such that the recombination efficiency of electrons and holes in the light-emitting layer 301 can be improved, thereby improving the light-emitting efficiency of the light-emitting structure 1 and enhancing the light-emitting intensity of the light-emitting structure 1.

It should be noted that the colors of the plurality of light-emitting layers 301 in the present application may be different. For example, the light emitted by the light-emitting layer 301 in the present application may include red light, green light, blue light, etc. The present application can adjust the value range of the included angle θ between the outer peripheral side of the light-emitting layer 301 of different colors and the substrate 2 according to the required brightness effect of the light-emitting structure 1.

In addition, the present application can also extend the first-type doped layer 302 to a part of the surface of the light-emitting layer 301 close to the substrate 2 and extend the second-type doped layer 303 partially to a part of the surface of the light-emitting layer 301 away from the substrate 2. At this time, the first-type doped layer 302 and the second-type doped layer 303 are still located on the opposite sides of the light-emitting layer 301, and the first-type doped layer 302 and the second-type doped layer 303 are provided at intervals. Thus, electrons and holes can be injected from the opposite sides of the light-emitting layer 301 respectively to realize the light-emitting function of the light-emitting layer 301. Meanwhile, in the embodiments of the present application, the contact surface of the first-type doped layer 302 with the second-type doped layer 303 and the light-emitting layer 301 can be increased, so that the recombination efficiency of electrons and holes in the light-emitting layer 301 can be improved, thereby improving the light-emitting efficiency of the light-emitting structure 1 and enhancing the light-emitting intensity of the light-emitting structure 1.

In the embodiments of the present application, the light-emitting structure 1 may include a reflective layer 306. The reflective layer 306 is located on the side of the light-emitting layer 301 away from the substrate 2, and the orthographic projection of the reflective layer 306 on the substrate 2 at least covers the orthographic projection of the light-emitting layer 301 on the substrate 2. The reflective layer 306 has good reflective performance.

Since the reflective layer 306 is provided in the present application, it can limit the light-emitting direction of each light-emitting unit 3.

Specifically, as shown in FIG. 3, when the light-emitting layer 301 emits light, the light emitted from the light-emitting layer 301 onto the reflective layer 306 is reflected by the reflective layer 306 and then emitted out towards the substrate 2. Therefore, Since the reflective layer 306 is provided in the present application, the side of the light-emitting layer 301 away from the substrate 2 can be defined as the non-light-emitting side and the side of the light-emitting layer 301 close to the substrate 2 can be defined as the light-emitting side. In the embodiments of the present application, both the first-type electrode 304 and the second-type electrode 305 are located on the non-light-emitting side of the light-emitting layer 301, which can avoid the occupation of the light-emitting area on the light-emitting side by the first-type electrode 304 and the second-type electrode 305, thereby greatly increasing the light-emitting region of each light-emitting unit 3 and further improving the light-emitting brightness of the light-emitting structure 1.

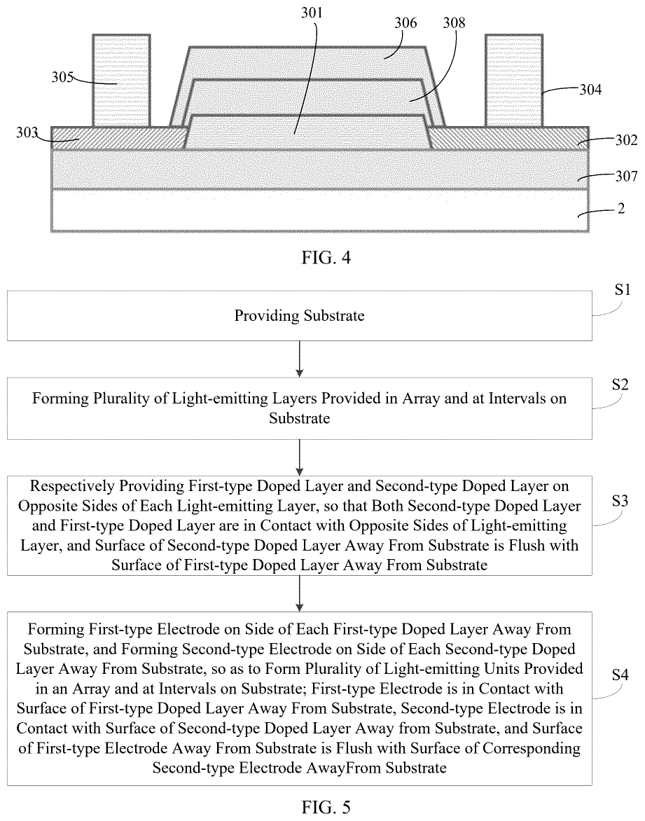

As shown in FIG. 4, in some embodiments of the present application, the surface of the first-type doped layer 302 away from the substrate 2 and the surface of the second-type doped layer 303 away from the substrate 2 can both be lower than the surface of the light-emitting layer 301 away from the substrate. At this time, the reflective layer 306 covers the surface of the light-emitting layer 301 away from the substrate 2 and the peripheral side surface of the light-emitting layer 301 that is not covered by the first-type doped layer 302 and the second-type doped layer 303, such that it can reduce or avoid the situation where the light emitted from the light-emitting layer 301 is emitted from the peripheral side surface of the light-emitting layer 301 that is not covered by the first-type doped layer 302 and the second-type doped layer 303 to the non-light-emitting side of the light-emitting layer 301, thereby reducing or avoiding the possibility of light leakage in the light-emitting structure 1.

In other embodiments of the present application, the surface of the first-type doped layer 302 away from the substrate 2 and the surface of the second-type doped layer 303 away from the substrate 2 can both be flush with the surface of the light-emitting layer 301 away from the substrate 2, such that it can increase the contact area of the first-type doped layer 302 and the second-type doped layer 303 with the outer peripheral side of the light-emitting layer 301, so as to improve the recombination efficiency of electrons and holes in the light-emitting layer 301, thereby improving the light-emitting efficiency of the light-emitting structure 1 and enhancing the light-emitting intensity of the light-emitting structure 1. When the light-emitting unit 3 includes a reflective layer, the reflective layer 306 can cover the surface of the light-emitting layer 301 away from the substrate 2.

In the embodiments of the present application, the surface of the reflective layer 306 away from the substrate 2 can be lower than the surfaces of the first-type doped layer 302 and the second-type doped layer 303 away from the substrate 2, but it is not limited thereto. The surface of the reflective layer 306 away from the substrate 2 can also be higher than the surfaces of the first-type doped layer 302 and the second-type doped layer 303 away from the substrate 2.

It should be understood that when the light-emitting unit 3 is bonded to the driving substrate 4, the first-type electrode 304 and the second-type electrode 305 in the light-emitting unit 3 are respectively bonded to the corresponding driving electrodes 41 on the driving substrate 4. The height of the driving electrode 41 is defined as H. If the surface of the reflective layer 306 away from the substrate 2 is higher than the surface of the first-type doped layer 302 (or the second-type doped layer 303) away from the substrate 2, the following condition should be met: the height difference between the surface of the reflective layer 306 away from the substrate 2 and the surface of the first-type doped layer 302 (or the second-type doped layer 303) away from the substrate 2 is less than or equal to H.

For example, when H is equal to 3 um, the height difference between the surface of the reflective layer 306 away from the substrate 2 and the surface of the first-type doped layer 302 (or the second-type doped layer 303) away from the substrate 2 is less than or equal to 3 um, so as to avoid the situation where the first-type electrode 304 and the second-type electrode 305 cannot be bonded to the driving electrode 41.

In the embodiments of the present application, the light-emitting structure 1 may also include a buffer layer 307. The buffer layer 307 is provided between the light-emitting layer 301 and the substrate 2, and the buffer layer 307 can cover the substrate 2. Since the buffer layer 307 is provided in the present application, it can prevent defects (such as dislocations and microcracks) from the substrate 2 from propagating to the structures on the substrate 2, such as the light-emitting layer 301, the first-type doped layer 302, and the second-type doped layer 303. Thus, the crystal quality and overall performance of the structures on the substrate 2, such as the light-emitting layer 301, the first-type doped layer 302, and the second-type doped layer 303, can be improved, so as to enhance the optical performance of the light-emitting structure 1.

In the embodiments of the present application, the light-emitting structure 1 may also include a protective layer 308. The protective layer 308 is disposed on the side of the light-emitting layer 301 away from the substrate 2, and the protective layer 308 covers the outer surface of the light-emitting layer 301.

It should be noted that the outer surface of the light-emitting layer 301 mentioned above refers to the surface of the light-emitting layer 301 exposed to the external environment.

For example, as shown in FIG. 4, when the heights of the first-type doped layer 302 and the second-type doped layer 303 are less than the height of the light-emitting layer 301, the outer surface of the light-emitting layer 301 refers to the side of the light-emitting layer 301 away from the substrate 2 and the peripheral side surface of the light-emitting layer 301 that is not covered by the first-type doped layer 302 and the second-type doped layer 303.

The protective layer 308 in the present application has good chemical stability, thermal stability, and optical performance. The protective layer 308 can prevent the light-emitting layer 301 from contacting and being passivated or even corroded by pollutants, moisture, oxygen, etc. in the external environment, thereby protecting the integrity and light-emitting performance of the light-emitting layer 301.

In the embodiments of the present application, the light-emitting unit 3 may also include both the protective layer 308 and the reflective layer 306. At this time, the protective layer 308 covers the outer surface of the light-emitting layer 301, and the protective layer 308 can be in direct contact with the outer surface of the light-emitting layer 301 to protect the integrity and light-emitting performance of the light-emitting layer 301. The reflective layer 306 can cover the surface of the protective layer 308 away from the light-emitting layer 301 and the peripheral side surface of the protective layer 308. Thus, the light emitted to the non-light-emitting side of the light-emitting layer 301 can be reflected to the light-emitting side of the light-emitting layer 301 through the reflective layer 306, so as to improve the light-emitting rate and thus enhance the light-emitting brightness of the light-emitting structure 1.

As shown in FIGS. 5 to 11, the embodiments of the present application provide a method for manufacturing a light-emitting structure. The manufacturing method includes:
S1. Providing a substrate.
S2. Forming a plurality of light-emitting layers provided in an array and at intervals on the substrate.
S3. Respectively providing a first-type doped layer and a second-type doped layer on the opposite sides of each light-emitting layer, so that both the second-type doped layer and the first-type doped layer are in contact with the opposite sides of the light-emitting layer, and the surface of the second-type doped layer away from the substrate is flush with the surface of the first-type doped layer away from the substrate.
S4. Forming a first-type electrode on the side of each first-type doped layer away from the substrate, and forming a second-type electrode on the side of each second-type doped layer away from the substrate, so as to form a plurality of light-emitting units provided in an array and at intervals on the substrate; the first-type electrode is in contact with the surface of the first-type doped layer away from the substrate, the second-type electrode is in contact with the surface of the second-type doped layer away from the substrate, and the surface of the first-type electrode away from the substrate is flush with the surface of the corresponding second-type electrode away from the substrate.

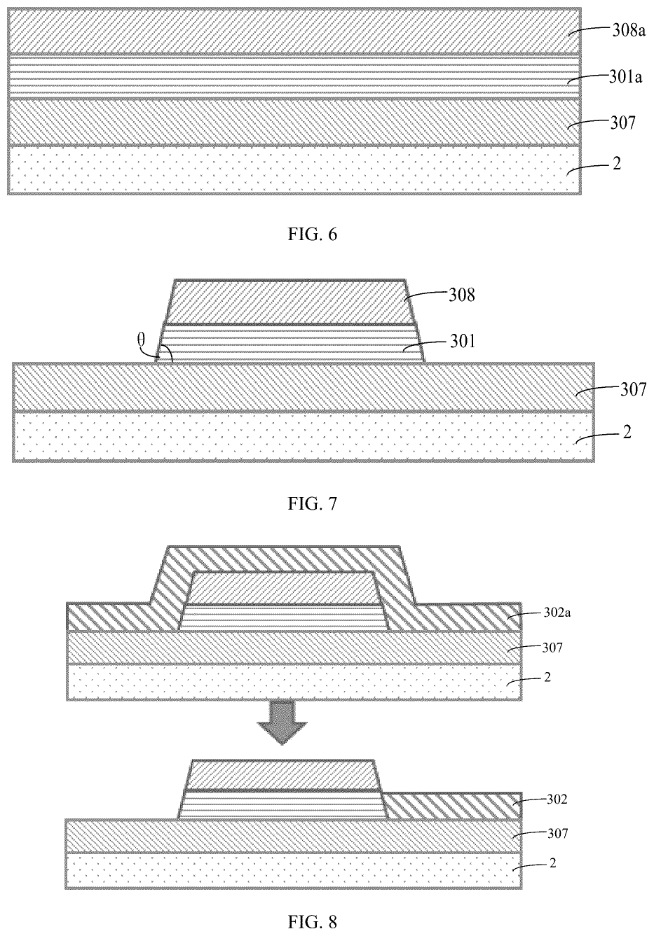

As shown in FIGS. 6 and 7, in the embodiments of the present application, when the light-emitting unit 3 includes the protective layer 308, the manufacturing method of forming the light-emitting layer 301 and the protective layer 308 may include: forming a light-emitting material 301a on the substrate 2, and forming a protective material on the side of the light-emitting material 301a away from the substrate 2, and patterning the light-emitting material 301a and the protective material to form the light-emitting layer 301 and the protective layer 308 covering the light-emitting layer 301.

In the present application, by successively forming the light-emitting material 301a and the protective material on the substrate 2 and then simultaneously forming the light-emitting layer 301 and the protective layer 308 through a single patterning process, the manufacturing process of the light-emitting structure I can be simplified, thereby improving the manufacturing efficiency of the light-emitting structure 1.

It should be noted that in the present application, the light-emitting material 301a and the protective material can be successively formed on the substrate 2 by means of continuous deposition, but it is not limited thereto. Any process that successively forms the light-emitting material 301a and the protective material on the substrate 2 other than deposition can be included in the embodiments of the present application.

Further, when the light-emitting structure I also includes the buffer layer 307, in the present application, the buffer layer 307, the light-emitting material 301a, and the protective material can be successively formed on the substrate 2 first, and the buffer layer 307 covers the substrate 2. The side of the buffer layer 307 away from the substrate 2 can be a horizontal plane to facilitate the manufacturing of structures such as the light-emitting layer 301, the first-type doped layer 302, and the second-type doped layer 303.

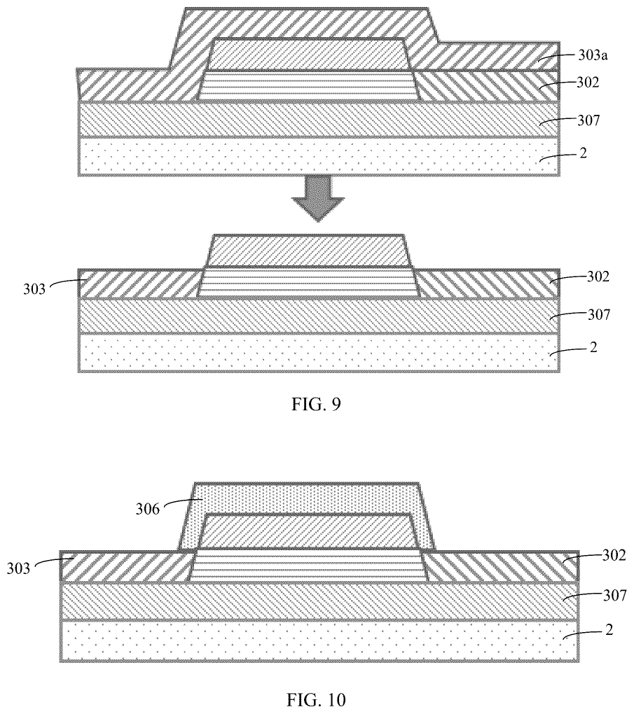

As shown in FIGS. 8 and 9, in an embodiment of the present application, the step of forming a plurality of light-emitting units 3 provided in an array and at intervals on the substrate 2 may include: first forming a first-type doped material 302a that entirely covers the substrate 2 and each light-emitting layer 301, and then patterning the first-type doped material 302a to form the first-type doped layer 302 on one side of the light-emitting layer 301, and then forming a second-type doped material 303a that entirely covers the substrate 2, each light-emitting layer 301, and each first-type doped layer 302, and then patterning the second-type doped material 303a to form the second-type doped layer 303 on the other side of the light-emitting layer 301.

It should be noted that the above “entirely covering” means that the formed first-type doped material 302a completely covers the surface of the substrate close to the light-emitting layer. Similarly, the formed second-type doped material 303a also completely covers the surface of the substrate close to the light-emitting layer.

The first-type doped material 302a in the present application can be P-type doped, and the second-type doped material 303a can be N-type doped, but it is not limited thereto. The doping types of the first-type doped material 302a and the second-type doped material 303a in the present application can be determined according to the actual situation of each light-emitting unit 3.

In the embodiments of the present application, the first-type doped material 302a and the second-type doped material 303a can be formed on the substrate 2 by means of deposition, but it is not limited thereto. Any process that forms the first-type doped material 302a and the second-type doped material 303a on the substrate 2 can be included in the embodiments of the present application.

The patterning process for the first-type doped material 302a and the second-type doped material 303a in the present application can be a photolithography process, but it is not limited thereto. Any process that patterns the first-type doped material 302a and the second-type doped material 303a into the first-type doped layer 302 and the second-type doped layer 303 respectively can be included in the embodiments of the present application.

In addition, in the present application, the first-type doped material 302a and the second-type doped material 303a can also be simultaneously formed at preset positions on the opposite sides of the outer periphery of the light-emitting layer 301, and the first-type doped layer 302 and the second-type doped layer 303 can be respectively formed on the opposite sides of the light-emitting layer 301 through a photolithography process. At this time, the first-type doped layer 302 and the second-type doped layer 303 can be fabricated through a single patterning process, thereby simplifying the manufacturing process of the first-type doped layer 302 and the second-type doped layer 303 and improving the manufacturing efficiency of the light-emitting structure 1.

It should be noted that when the first-type doped material 302a and the second-type doped material 303a are simultaneously formed at preset positions on the opposite sides of the outer periphery of the light-emitting layer 301, between two adjacent light-emitting layers 301, the preset position for setting the first-type doped material 302a should be spaced apart from the preset position for setting the second-type doped material 303a to avoid the problem that after the adjacent first-type doped material 302a and the second-type doped material 303a are in contact with each other, the two types of carriers (electrons and holes) in the first-type doped material 302a and the second-type doped material 303a are rapidly recombined in the contact region, which leads to a decrease in the carrier concentration and a decrease in the light-emitting performance of the light-emitting structure 1.

In the embodiments of the present application, after forming the light-emitting layer 301 and before forming the first-type doped layer 302 or the second-type doped layer 303, the manufacturing method includes: processing the corresponding outer periphery of the light-emitting layer 301 to remove the passivation layer formed by oxidation of the outer periphery of the light-emitting layer 301.

The above “outer periphery” refers to the part where the first-type doped layer 302 or the second-type doped layer 303 is in contact with the light-emitting layer 301.

It should be noted that after the light-emitting layer 301 is formed, it is very easy to react with oxygen in the external environment to form a passivation layer. If the first-type doped layer 302 and the second-type doped layer 303 are directly formed on the outer periphery of the light-emitting layer 301 without removing the passivation layer on the outer surface of the light-emitting layer 301, when the carriers in the first-type doped layer 302 and the second-type doped layer 303 are transmitted to the light-emitting layer 301, the passivation layer will hinder the effective transmission of the carriers, which will reduce the recombination efficiency of the carriers and lead to a weakening of the light-emitting intensity of the light-emitting structure 1.

As shown in FIGS. 2 and 10, in the embodiments of the present application, when the light-emitting unit 3 includes the reflective layer 306, the step after forming the first-type doped layer 302 and the second-type doped layer 303 and before forming the first-type electrode 304 and the second-type electrode 305 may include: forming a reflective material on a side of the light-emitting layer 301 away from the substrate 2, and patterning the reflective material to form the reflective layer 306. The orthographic projection of the reflective layer 306 on the substrate 2 at least covers the orthographic projection of the light-emitting layer 301 on the substrate 2.

The reflective material can be materials with good reflective performance such as silver and aluminum.

It should be noted that the formation order of the reflective layer 306 and the first-type electrode 304 and the second-type electrode 305 in the present application can be exchanged. That is, in the present application, after forming the first-type doped layer 302 and the second-type doped layer 303, the reflective layer 306 can be first formed on the side of the light-emitting layer 301 away from the substrate 2, and then the first-type electrode 304 can be formed on the first-type doped layer 302, and the second-type electrode 305 can be formed on the second-type doped layer 303.

When the light-emitting unit 3 includes both the protective layer 308 and the reflective layer 306, the protective layer 308 can be first formed on the side of the light-emitting layer 301 away from the substrate 2, and then the reflective layer 306 can be formed on the side of the protective layer 308 away from the light-emitting layer 301.

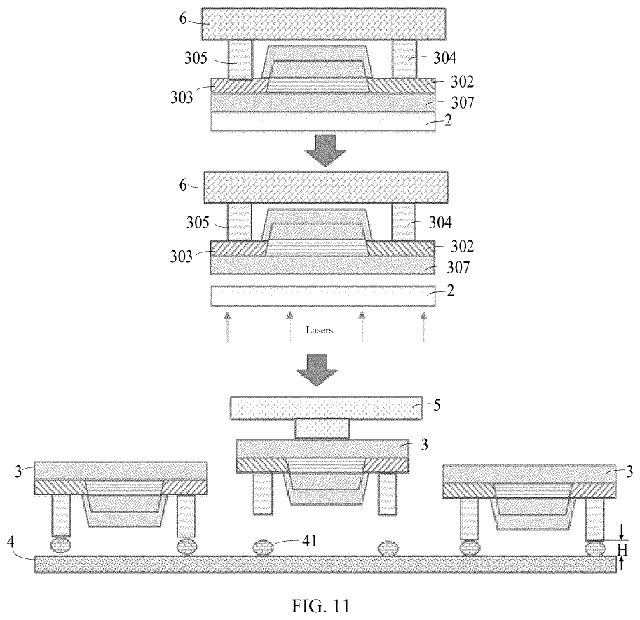

As shown in FIG. 11, in the present application, after the light-emitting structure 1 is formed, the light-emitting structure 1 can be transferred to a temporary substrate 6, and the first-type electrode 304 and the second-type electrode 305 in the light-emitting unit 3 are bonded to the temporary substrate 6. By irradiating the side of the substrate 2 away from the light-emitting layer 301 with a laser, the light-emitting unit 3 is peeled off from the substrate 2. A transfer device 5 is provided. The transfer device 5 is used to separate the light-emitting unit 3 from the temporary substrate 6 and transfer the light-emitting unit 3 to the driving substrate 4. The first-type electrode 304 and the second-type electrode 305 are respectively connected to the corresponding driving electrodes 41 on the driving substrate 4, so as to realize the transfer of each light-emitting unit 3.

The present application provides a display device. The display device may include a main board and any of the above light-emitting structures 1. The main board is electrically connected to each light-emitting unit 3 in the light-emitting structure 1. The main board controls the light-emitting brightness of each light-emitting unit 3 by sending signals to each light-emitting unit 3, thereby realizing the display function of the display device.

It should be noted that the display device in the present application can be a micro LED display device, a miniature light-emitting diode (mini LED) display device, etc.

In addition, the terms “first” and “second” are only used for the purpose of description and cannot be construed as indicating or implying relative importance or implicitly specifying the number of indicated technical features. Thus, a feature defined with “first” or “second” may explicitly or implicitly include one or more of such features. In the description of the present application, “a plurality of” means two or more, unless otherwise specifically defined.

It should be noted that terms such as “upper”, “lower”, “left”, and “right” are only used for differentiation to facilitate description and do not impose any restrictions on the orientation of the embodiments of the present invention. For example, the “upper” may actually be the “lower”, “left”, “right”, or other orientations in practice. In the present application, unless otherwise clearly defined and limited, terms such as “assembly” and “connection” should be understood in a broad sense. For example, it can be a fixed connection, a detachable connection, or an integrated connection; it can be a mechanical connection or an electrical connection; it can be a direct connection or an indirect connection through an intermediate medium, and it can be the internal communication between two components or the interaction relationship between two components. For those skilled in the art, the specific meanings of the above terms in the present application can be understood according to specific situations.

In the description of this specification, the description with reference to terms such as “some embodiments” and “for example” means that specific features, structures, materials, or characteristics described in combination with the embodiment or example are included in at least one embodiment or example of the present application. In this specification, the schematic representation of the above terms does not necessarily refer to the same embodiment or example. Moreover, the described specific features, structures, materials, or characteristics can be combined in an appropriate manner in any one or more embodiments or examples. In addition, without mutual contradiction, those skilled in the art can combine and integrate different embodiments or examples described in this specification and the features of different embodiments or examples.

Although the embodiments of the present application have been shown and described above, it can be understood that the above embodiments are exemplary and should not be construed as limiting the present application. Those skilled in the art can make changes, modifications, substitutions, and variations to the above embodiments within the scope of the present application. Therefore, any changes or modifications made according to the claims and the specification of the present application shall fall within the scope covered by the patents of the present application.

What is claimed is:

1. A light-emitting structure, comprising:
a substrate;
a plurality of light-emitting units provided in an array and at intervals on the substrate;
wherein each light-emitting unit comprises a light-emitting layer, a first-type doped layer, a second-type doped layer, a first-type electrode and a second-type electrode;
in each light-emitting unit: the second-type doped layer and the first-type doped layer are in contact with opposite sides of the light-emitting layer, a surface of the second-type doped layer away from the substrate is flush with a surface of the first-type doped layer away from the substrate;
the first-type electrode is in contact with the surface of the first-type doped layer away from the substrate, and the second-type electrode is in contact with the surface of the second-type doped layer away from the substrate; and
the surface of the first-type electrode away from the substrate is flush with the surface of the second-type electrode away from the substrate.

2. The light-emitting structure according to claim 1, wherein the light-emitting structure comprises a reflective layer, the reflective layer is located on a side of the light-emitting layer away from the substrate, and an orthographic projection of the reflective layer on the substrate at least covers an orthographic projection of the light-emitting layer on the substrate.

3. The light-emitting structure according to claim 1, wherein the surface of the first-type doped layer away from the substrate and the surface of the second-type doped layer away from the substrate are both flush with the surface of the light-emitting layer away from the substrate.

4. The light-emitting structure according to claim 2, wherein the surface of the first-type doped layer away from the substrate and the surface of the second-type doped layer away from the substrate are both lower than a surface of the light-emitting layer away from the substrate;
the reflective layer covers the surface of the light-emitting layer away from the substrate and a peripheral side surface of the light-emitting layer that is not covered by the first-type doped layer and the second-type doped layer.

5. The light-emitting structure according to claim 1, wherein in a direction away from the substrate, an outer peripheral side of the light-emitting layer inclines towards a center of the light-emitting layer;
an included angle θ between an outer peripheral side of the light-emitting layer and the substrate is greater than or equal to 45° and less than 90°.

6. The light-emitting structure according to claim 1, further comprising a buffer layer, wherein the buffer layer is provided between the light-emitting layer and the substrate, and the buffer layer covers the substrate.

7. The light-emitting structure according to claim 4, wherein each light-emitting unit further comprises a protective layer, and the protective layer is provided between the light-emitting layer and the reflective layer.

8. A method for manufacturing a light-emitting structure, comprising:
providing a substrate;
forming a plurality of light-emitting layers provided in an array and at intervals on the substrate;
respectively providing a first-type doped layer and a second-type doped layer on opposite sides of each light-emitting layer, so that both the second-type doped layer and the first-type doped layer are in contact with the opposite sides of each light-emitting layer, and a surface of the second-type doped layer away from the substrate is flush with a surface of the first-type doped layer away from the substrate; and
forming a first-type electrode on a side of each first-type doped layer away from the substrate, and forming a second-type electrode on a side of each second-type doped layer away from the substrate, to form a plurality of light-emitting units provided in an array and at intervals on the substrate;
wherein the first-type electrode is in contact with the surface of the first-type doped layer away from the substrate, the second-type electrode is in contact with the surface of the second-type doped layer away from the substrate, and the surface of the first-type electrode away from the substrate is flush with a surface of a corresponding second-type electrode away from the substrate.

9. The method according to claim 8, wherein forming the plurality of light-emitting units provided in an array and at intervals on the substrate comprises:
forming a first-type doped material that covers the substrate and each light-emitting layer entirely, and then patterning the first-type doped material to form the first-type doped layer on one side of each light-emitting layer; and
forming a second-type doped material that covers the substrate, each light-emitting layer and each first-type doped layer entirely, and then patterning the second-type doped material to form the second-type doped layer on another side of each light-emitting layer.

10. The method according to claim 8, wherein after forming the plurality of light-emitting layers and before forming the first-type doped layer or the second-type doped layer, the method further comprises:
processing an outer peripheral side corresponding to each light-emitting layer to remove a passivation layer formed by oxidation of the outer peripheral side corresponding to each light-emitting layer; and/or
each light-emitting unit comprises a protective layer, and forming each light-emitting layer and the protective layer comprises:
forming a light-emitting material on the substrate, and forming a protective material on a side of each light-emitting material away from the substrate; and
patterning the light-emitting material and the protective material to form each light-emitting layer and the protective layer covering each light-emitting layer.

11. The method according to claim 8, wherein each light-emitting unit comprises a reflective layer, and after forming the first-type doped layer and the second-type doped layer and before forming the first-type electrode and the second-type electrode, the method further comprises:
forming a reflective material on the side of each light-emitting layer away from the substrate, and patterning the reflective material to form the reflective layer; and
an orthographic projection of the reflective layer on the substrate at least covers an orthographic projection of each light-emitting layer on the substrate.

12. A display device, comprising a main board and a light-emitting structure, wherein the main board is electrically connected to each light-emitting unit in the light-emitting structure;
wherein the light-emitting structure comprises:
a substrate;
a plurality of light-emitting units provided in an array and at intervals on the substrate;
wherein each light-emitting unit comprises a light-emitting layer, a first-type doped layer, a second-type doped layer, a first-type electrode and a second-type electrode;
in each light-emitting unit: the second-type doped layer and the first-type doped layer are in contact with opposite sides of the light-emitting layer, a surface of the second-type doped layer away from the substrate is flush with a surface of the first-type doped layer away from the substrate;
the first-type electrode is in contact with the surface of the first-type doped layer away from the substrate, and the second-type electrode is in contact with the surface of the second-type doped layer away from the substrate; and
the surface of the first-type electrode away from the substrate is flush with the surface of the second-type electrode away from the substrate.

13. The display device according to claim 12, wherein the light-emitting structure comprises a reflective layer, the reflective layer is located on a side of the light-emitting layer away from the substrate, and an orthographic projection of the reflective layer on the substrate at least covers an orthographic projection of the light-emitting layer on the substrate.

14. The display device according to claim 12, wherein the surface of the first-type doped layer away from the substrate and the surface of the second-type doped layer away from the substrate are both flush with the surface of the light-emitting layer away from the substrate.

15. The display device according to claim 13, wherein the surface of the first-type doped layer away from the substrate and the surface of the second-type doped layer away from the substrate are both lower than a surface of the light-emitting layer away from the substrate;
the reflective layer covers the surface of the light-emitting layer away from the substrate and a peripheral side surface of the light-emitting layer that is not covered by the first-type doped layer and the second-type doped layer.

16. The display device according to claim 12, wherein in a direction away from the substrate, an outer peripheral side of the light-emitting layer inclines towards a center of the light-emitting layer;
an included angle θ between an outer peripheral side of the light-emitting layer and the substrate is greater than or equal to 45° and less than 90°.

17. The display device according to claim 12, further comprising a buffer layer, wherein the buffer layer is provided between the light-emitting layer and the substrate, and the buffer layer covers the substrate.

18. The display device according to claim 15, wherein each light-emitting unit further comprises a protective layer, and the protective layer is provided between the light-emitting layer and the reflective layer.
